(19) United States
(12) Patent Application Publication
(10) Pub. No.: US 2012/0167959 A1
(43) Pub. Date: Jul. 5, 2012

(54) PHOTOVOLTAIC MODULE HAVING A PLANAR CELL CONNECTOR

(75) Inventors: Harry Wirth, Merzhausen (DE); Hans-Ulrich Wagner, Boostedt (DE); Jens Kalmbach, Pfalzgrafenweiler (DE); Bernd Hirzler, Endingen (DE); Beat Strebel, Rodersdorf (CH)

(73) Assignee: Fraunhofer-Gesellschaft zur Forderung der Angewandten Forschung E.V., Munchen (DE)

(21) Appl. No.: 13/375,852

(22) PCT Filed: Jun. 1, 2010
(86) PCT No.: PCT/EP2010/003320

§ 371 Date: Mar. 22, 2012

(30) Foreign Application Priority Data
Jun. 4, 2009 (DE) 10 2009 023 901.4

(51) Int. Cl. H01L 31/048; H01L 31/05

(52) U.S. Cl. 136/251; 136/244

(57) ABSTRACT

The invention relates to a photovoltaic module made of at least two solar cells, wherein said cells are connected at least in regions by a planar cell connector. The cell connector is made of at least one porous carrier layer and at least one conductor structure disposed on the side of the carrier layer facing away from the solar cells. The system of planar cell connectors are used in producing wafer-based photovoltaic modules, primarily of return contact cells having an arbitrary contact arrangement in the plane.

The invention relates to a photovoltaic module which consists of at least two solar cells, these being connected at least in regions by a planar cell connector. The cell connector consists of at least one porous carrier layer and at least one conductor structure which are disposed on the side of the carrier layer orientated away from the solar cells. The systems of planar cell connectors are used in the production of wafer-based photovoltaic modules, above all made of rear-contact cells which have any contact arrangement in the surface.

Solar cells must be connected electrically in series in order to reduce the currents and hence the ohmic conduction losses. In the case of rear-contact cells, the object resides in connecting contact points situated on the rear-side of the cell to the opposite-pole contact points of a neighbouring cell via one or more lines. Electrical insulation in sections between line and cell can thereby be necessary, in particular in the case of cells, the contact points of which are not disposed entirely at the cell edge.

It is advantageous for efficient module production to prepare the connection lines on a carrier material in the desired arrangement. Then the cells only need to be positioned and contacted on these planar cell connectors, for example by soldering or gluing.

In a subsequent laminating process, a liquid-viscous material must penetrate between the cells and the cover layers of the module. When this cures, it produces a mechanical bond of the module components.

U.S. Pat. No. 5,951,786 describes two variants of a cell connector. In the first method, a flat, structured conductor layer is situated on the rear-side foil of the module. This method has the disadvantage that normal soldering temperatures can damage the rear-side foil.

In the second method, a flat, structured layer is situated on the side of a flat carrier orientated towards the solar cells. Openings or pores in the carrier allow penetration of encapsulation material in the laminating process.

A disadvantage of this embodiment is the risk of short circuits in the case where the conductors must be guided over those regions of the cell which have opposite polarity. This problem occurs occasionally in cells which have their contacts disposed at the edge, and it occurs regularly in cells, the contacts of which are situated in the cell surface.

DE 10 2005 053 363 describes a 3-layer cell connector in the case of which an insulating layer separates two conductor layers. The disadvantage of this embodiment is the requirement for step-wise application by shingle technology. Hence, no continuous cell connector in the dimensions of the PV module can be prepared in one step.

Starting herefrom, it was the object of the present invention to provide photovoltaic modules, the production of which is easy to implement and thus enable efficient module production.

This object is achieved by the photovoltaic module having the features of claim 1. The further dependent claims reveal advantageous developments.

According to the invention, a photovoltaic module is provided which consists of at least two solar cells which are connected at least in regions by a planar cell connector, the cell connector having at least one porous carrier layer and at least one conductor structure which is disposed on the side of the carrier layer orientated away from the solar cells.

The core of the present invention is hence a planar cell connector which can be produced with material costs which are only slightly above the costs of the conductor material. The described planar cell connector enables rapid assembly of the solar cells, which are disposed in the manner of a matrix, in module production. At the same time, a cell connection having particularly low series resistor losses in the range of 0.5 to 1.5% can be achieved for planar contact cells, for instance according to metal wrap through technology (MWT).

There is thereby understood according to the invention by a porous carrier layer, a layer which has non-directional pores. This has hence on average uniform permeability, for example for gases and liquid-viscous media. A perforated layer which has spatially directed channels or pores should consequently not be equated with the porous carrier layer according to the invention.

Preferably, the porous carrier layer has recesses in which the conductor structure extends such that the conductor structure is contacted electrically with the solar cells. In particular, the conductor structure is shaped in the region of the recesses of the carrier layer in the direction of the solar cells. Such shapings are beads or steps. The height of the bead or step thereby corresponds essentially to the thickness of the carrier layer.

In a further preferred variant, the conductor structure in the region of the recesses of the carrier layer has at least one stress-relieving element. The stress-relieving element hereby causes a reduction in the stresses in the conductor structure and between the conductor structure and the solar cell at the contact points. There are preferred as stress-relieving elements, beads, arcs or other indirect connection paths. For stress-relief in the region of the contact points, also structures which effect a stronger local interlocking with the encapsulation material can be introduced into the conductor.

The conductor structure is preferably a wire, in particular a flat or round wire, but can also be configured as a stamped part. Another possibility for the production of the conductor structure resides in etching the structure directly on the carrier layer.

The conductor structure preferably consists of an electrically conductive core, in particular made of copper, and also a casing made of a solder material. There are possible as solder material, tin, silver or alloys hereof. The electrically conductive core preferably consists of a metal, in particular copper or aluminium. It is likewise possible to use other metals or conductively doped, non-metallic materials, in particular polymer materials. Preferably, the at least one conductor structure in the region of the recess of the carrier layer is connected to the at least one carrier layer integrally, in particular by gluing, soldering, bonding or welding, or frictionally, in particular by stitching or weaving, or in a form fit, in particular by embossing.

Preferably, the wires extend essentially parallel to the edges of the solar cells, the wires having, per solar cell, at least one interruption with at least two contact points to the solar cell. It is thereby preferred that the wires are disposed in 2 to 6 groups, in particular in 2 to 3 groups.

The at least one carrier layer preferably consists of an open-pore nonwoven or fabric. Dimensionally stable nonwovens made of bonded fibres of glass or a polymer material are particularly preferred.

The fibres are preferably fixed by means of a binding agent. It is not required here that the fibres are woven (so-called nonwovens).

A further preferred embodiment provides that the carrier layer has an adhesive layer for fixing the at least one conductor structure. A preferred embodiment of the porous carrier layer is thereby a glass fibre nonwoven, consisting of non-woven glass fibres with an adhesive coating.

The recesses in the carrier layer can be produced by stamping, cutting or boring.

Furthermore, it is preferred that the photovoltaic module has at least a first cover layer on the side of the photovoltaic module orientated towards the light incidence, which cover layer has essentially transparent properties. The essentially transparent properties relate here to the wavelength range which can be achieved for conversion into electrical energy by solar cells.

Likewise, it is preferred that the photovoltaic module has at least a second cover layer on the side of the photovoltaic module orientated away from the light incidence.

Furthermore, an encapsulation material can be filled between the cover layers and the solar cells and/or the at least one carrier layer.

The solution according to the invention is hence based on a planar cell connector in which the conductor layer is disposed on the side of a porous carrier layer orientated away from the solar cells. The carrier layer and the encapsulation material which penetrates during the laminating process hence produces an insulating layer between conductor portions and cell portions with opposite polarity. Recesses are provided in the carrier at the contact points so that a connection between conductor structure and solar cell can be effected there. For this purpose, the conductor structure changes from the side of the carrier layer which is orientated away from the cell to that orientated towards the cell. The electrical and mechanical connection can be effected by soldering, gluing, welding, bonding or any other joining techniques. Likewise, also frictional connections, in particular by stitching or weaving, or form-fit connections, in particular by embossing, are however possible.

The conductor structure has recesses or free areas through which a liquid-viscous encapsulation material can penetrate. The material penetrates further through the carrier layer and produces finally a connection between the rear cover layer of the module and the solar cell rear-sides.

The subject according to the invention is intended to be explained in more detail with reference to the subsequent Figures without wishing to restrict the latter to the special embodiments shown here.

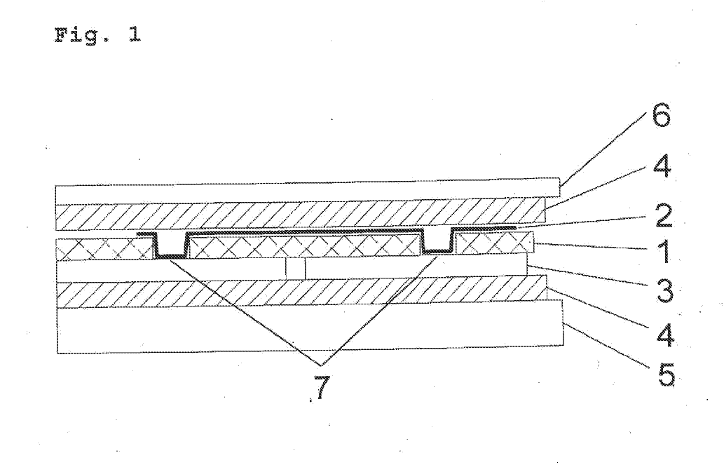

FIG. 1 shows a first embodiment according to the invention in cross-section.

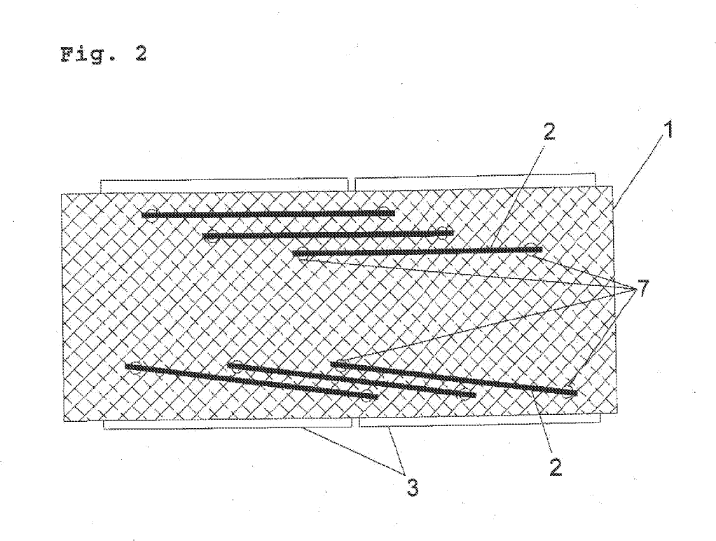

FIG. 2 shows an embodiment according to the invention in plan view.

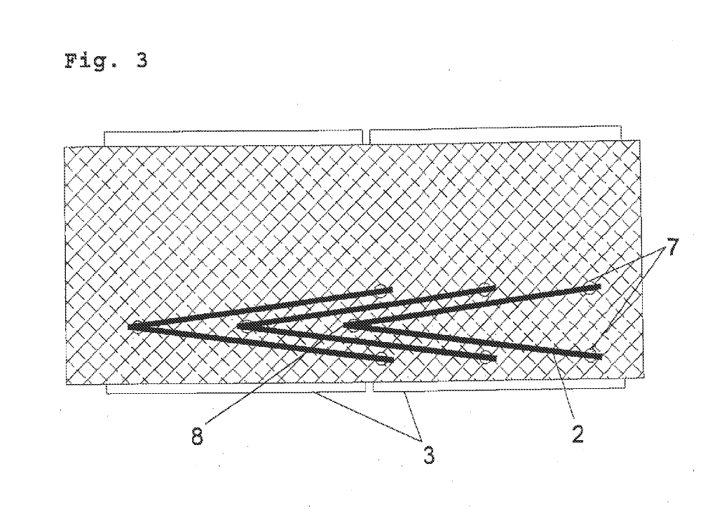

FIG. 3 shows a further embodiment according to the invention in plan view.

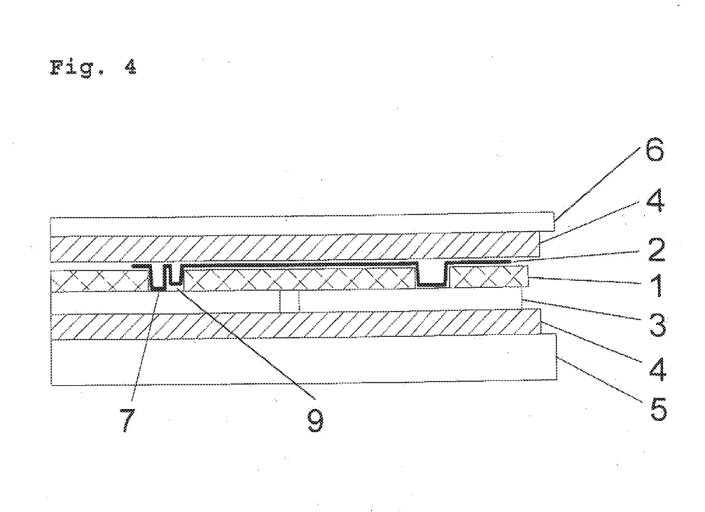

FIG. 4 shows an embodiment according to the invention in cross-section.

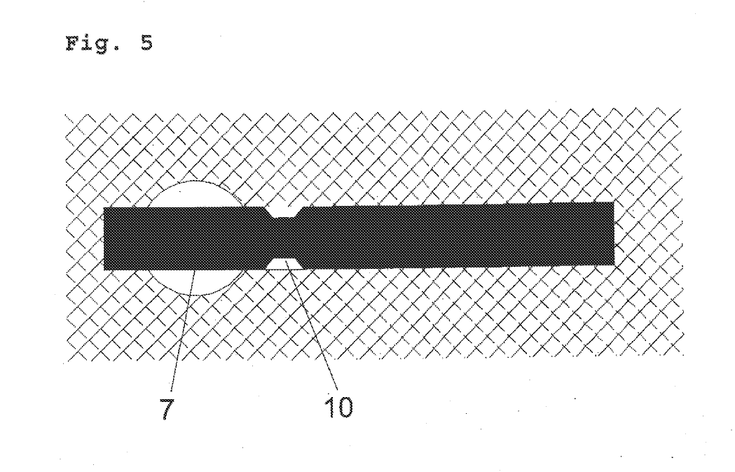

FIG. 5 shows an embodiment of the cell connector according to the invention.

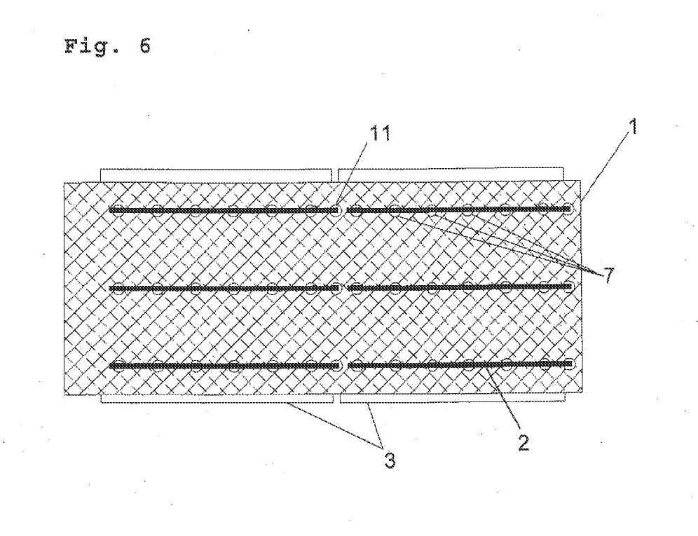

FIG. 6 shows a further embodiment according to the invention in plan view.

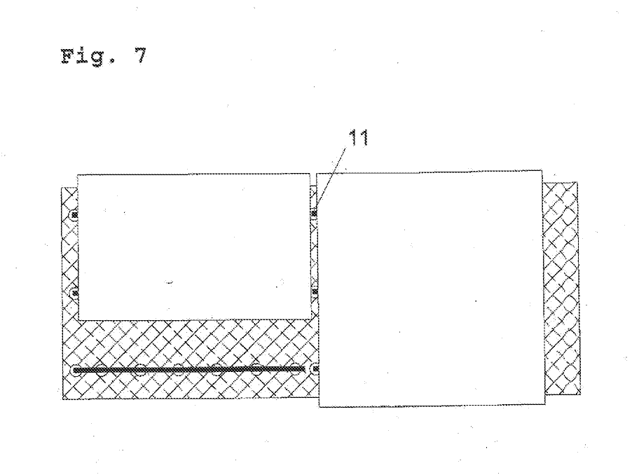

FIG. 7 shows a further embodiment according to the invention in plan view.

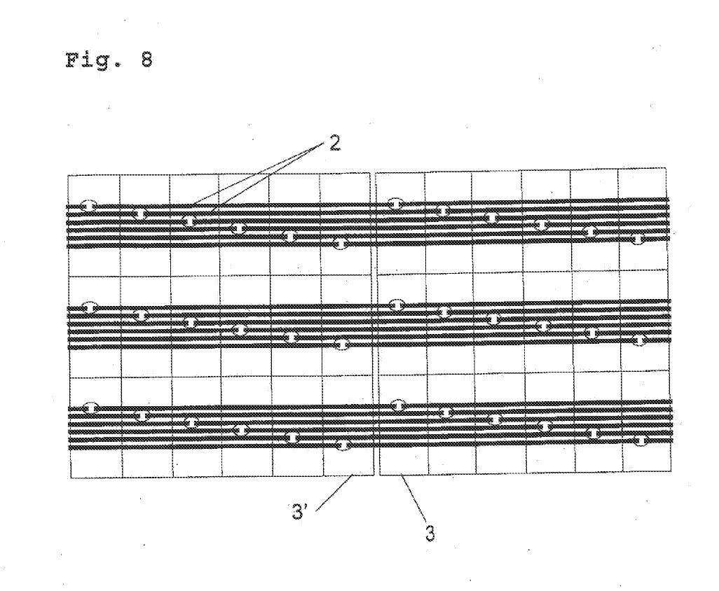

FIG. 8 shows a further embodiment according to the invention in plan view.

FIG. 1 shows a preferred embodiment in cross-section with carrier 1, conductor 2, cells 3, encapsulation material 4, front cover layer 5, rear cover layer 6, contact points 7. Recesses are provided at the contact points in the carrier 1 and beads in the conductor 2. In the laminating process, the encapsulation layer 4 penetrates partially into the carrier 1.

FIG. 2 shows a preferred embodiment in plan view. The conductors 2 are configured as flat wires. The carrier 1 has holes at the contact points 7. The conductors can be situated in any arrangement relative to the cell edge, in the illustration they are disposed parallel (at the top) or obliquely (at the bottom) relative to the edge of the cell 3.

FIG. 3 shows an embodiment as a folded flat wire which connects three points on two cells. The flat wire was folded at the point 8.

FIG. 4 shows an embodiment in which, in addition to the contact point 7, an additional bead 9 is provided to relieve the strain on the contact point.

FIG. 5 shows a flat conductor in plan view which has a waist 10 in the vicinity of the contact point 7. In conjunction with the surrounding encapsulation material, strain relief is achieved for the contact point.

The planar cell connector according to the invention can also be used for conventional solar cells (having a contact arrangement on both sides). FIG. 6 shows an embodiment in which contacts are present between cell connector and cell at the points 7. At the points 11 in the cell intermediate space, front-side and rear-side cell connectors are connected.

In the preferred embodiment of the carrier as glass fibre nonwoven, also use of the planar cell connector between the first cover layer and the cell matrix is possible. Because of the similar refractive indices of nonwoven and encapsulation material, significant losses in optical efficiency do not result.

FIG. 7 shows the arrangement of a second planar cell connector, corresponding to FIG. 6, in front of the cells with the connection points 11 for the rear-side planar cell connector of FIG. 6. The left solar cell is represented shortened for a better overview.

FIG. 8 shows an embodiment with connectors 2 which extend parallel to the edges of the solar cells 3, 3′. 18 Connectors 2 are assigned, in the present case, to a single solar cell 3 and are disposed in 3 groups. The ends of the connectors 2 contact respectively the emitter of a solar cell 3 and the base of the adjacent solar cell 3′ through oval holes in the carrier layer. The carrier layer is not illustrated in FIG. 8.

1. A photovoltaic module consisting of at least two solar cells which are connected at least in regions by a planar cell connector, the cell connector having at least one porous carrier layer and at least one conductor structure which is disposed on the side of the carrier layer orientated away from the solar cells.

2. The photovoltaic module according to claim 1, wherein the porous carrier layer has recesses in which the conductor structure extends such that the conductor structure is contacted electrically with the solar cells.

3. The photovoltaic module according to claim 2, wherein the conductor structure is shaped in the region of the recesses of the carrier layer in the direction of the solar cells, in particular in the form of a bead or a step.

4. The photovoltaic module according to claim 3, wherein the height of the bead or step corresponds essentially to the thickness of the carrier layer.

5. The photovoltaic module according to claim 1, wherein the conductor structure in the region of the recesses of the carrier layer has at least one stress-relieving element, in particular in the form of a bead or an arc.

6. The photovoltaic module according to claim 1, wherein the at least one conductor structure is a wire, in particular a flat or round wire, or a structure which is stamped or etched on the carrier layer.

7. The photovoltaic module according to claim 6, wherein the wire has an electrically conductive core, in particular made of copper, and a casing made of a solder material, in particular made of tin, silver or alloys hereof.

8. The photovoltaic module according to claim 7, wherein the core consists of a metal, in particular copper or aluminium, or a conductively doped, non-metallic material, in particular a polymer material.

9. The photovoltaic module according to claim 1, wherein the at least one conductor structure in the region of the recess of the carrier layer is connected to the at least one carrier layer integrally, in particular by gluing, soldering, bonding or welding, or frictionally, in particular by stitching or weaving, or in a form fit, in particular by embossing.

10. The photovoltaic module according to claim 1, wherein the at least one carrier layer consists of an open-pore nonwoven or fabric or essentially comprises this.

11. The photovoltaic module according to claim 1, wherein the at least one carrier layer consists of a fibrous material, in particular made of glass or polymer materials, or essentially comprises this.

12. The photovoltaic module according to claim 11, wherein the fibrous material is not interwoven, rather is fixed by at least one binding agent.

13. The photovoltaic module according to claim 1, wherein the photovoltaic module has at least a first cover layer on the side of the photovoltaic module orientated towards the light incidence, which cover layer has essentially transparent properties.

14. The photovoltaic module according to claim 1, wherein the photovoltaic module has at least a second cover layer on the side of the photovoltaic module orientated away from the light incidence.

15. The photovoltaic module according to claim 14, wherein an encapsulation material is disposed between the cover layers and the solar cells and/or the at least one carrier layer.
